(19) United States
(12) Patent Application Publication
(10) Pub. No.: US 2009/0098307 A1
(43) Pub. Date: Apr. 16, 2009

(54) MANUFACTURING METHOD FOR FAR-INFRARED IRRADIATING SUBSTRATE

(75) Inventors: Po-Kai CHIU, Hsinchu City (TW); Wen-Hao CHO, Hsinchu City (TW); Han-Chang PAN, Taichung City (TW); Yung-Sheng LIN, Changhua County (TW); Ting-Kai LEUNG, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignees: NATIONAL APPLIED RESEARCH LABORATORIES, Taipei (TW); TAIPEI MEDICAL UNIVERSITY, Taipei City (TW)

(21) Appl. No.: 12/035,680

(22) Filed: Feb. 22, 2008

(30) Foreign Application Priority Data
Oct. 11, 2007 (TW) 96138079

(51) Int. Cl. C23C 14/48; C23C 16/44

(52) U.S. Cl. 427/530; 427/585

(57) ABSTRACT

A manufacturing method for a far-infrared irradiating substrate is provided. The manufacturing method comprises steps of providing a substrate, providing a far-infrared irradiating material and evaporating the far-infrared irradiating material to form a thin film onto the substrate. The far-infrared irradiating substrate provided by the present invention not only has a high emission coefficient of far-infrared ray, but also do not cause a potential exposure of an ionizing radiation.

### FIELD OF THE INVENTION

The present invention relates to a method for manufacturing a far-infrared irradiating substrate, and more particularly to a method for manufacturing a far-infrared irradiating substrate by means of an evaporation.

### BACKGROUND OF THE INVENTION

Far-infrared radiation is a form of electromagnetic radiation having a wavelength range of 3 to 1000 micrometers. Far-infrared rays (FIR) are part of the sunlight spectrum which is invisible to the naked eye. It also known as biogenetic rays (between 6 to 14 microns). Biogenetics rays have been proven by scientists to promote the growth and health of living cells especially in plants, animals and human beings. Far infrared radiation may help improve blood circulation, strengthen the cardiovascular system, relax muscles and increase flexibility, relieve pain, deep cleanse skin, remove toxins and mineral waste, burn calories and controls weight, improve the immune system, reduce stress and fatigue, eliminate waste from the body, reduce the acidic level in our body and improve the nervous system.

However, some of the current commercial far-infrared irradiating products still contain excess rare elements, wherein the radioactive irradiation emitted therefrom might bring about the potential dangerous threat to human body.

Additionally, in the conventional manufacturing process for far-infrared irradiating textiles, the mixture of ceramic powders and fibrous macromolecules that forms the fibrous filament is usually adopted as far-infrared irradiating material, whereby the fibrous filaments could be made into various kinds of far-infrared textiles. Alternatively, the far-infrared irradiating materials could be adhered to the textiles or yards in a dipping, a printing or a plating way.

However, the maximal content of far-infrared irradiating material in the mentioned fibrous filaments is approximately 5% that cannot provide the sufficient amount of far-infrared ray since the additives of the fibrous macromolecules might lower down the fibrous strength and wear the spinning nozzle. Besides, the factors of the larger diameter of far-infrared irradiating ceramic powders and the thinner fibrous filaments might result in that the far-infrared ceramic powders cannot completely buried within the filaments. Thus, the far-infrared ceramic powders might gradually peel off from the filaments, whereby the strength of emitting far-infrared ray will be highly decreased.

From the above description, it is known that how to provide a kind of far-infrared irradiating product with a better adhesion and a less potential treat of ionized radiation has become a major problem waited to be solved. In order to overcome the drawbacks in the prior art, an improved far-infrared irradiating product is provided. The particular design in the present invention not only solves the problems described above, but also is easy to be implemented. Thus, the invention has the utility for the industry.

### SUMMARY OF THE INVENTION

In accordance with one aspect of the present invention, a manufacturing method for a far-infrared irradiating substrate is provided. The manufacturing method comprises steps of providing a substrate into a vacuum chamber, filling a first gas into the vacuum chamber, inputting a far-infrared irradiating material into the vacuum chamber and evaporating and depositing the far-infrared irradiating material onto the substrate to form a thin film thereon.

Preferably, the evaporating step further comprises a step of providing a high-energy electron beam to the vacuum chamber.

Preferably, the evaporating step further comprises a step of treating a surface of the substrate by means of an ion source before the step of providing the high-energy electron beam to the vacuum chamber.

Preferably, the step of treating the surface further comprises a step of filling a second gas into the vacuum chamber for igniting the ion source, the first gas includes an oxygen, and the second gas is one selected from a group consisting of an argon, an oxygen, a nitrogen and a combination thereof.

Preferably, the evaporating step further comprises steps of controlling a gas flow rate in the vacuum chamber in a range of 10 to 200 c.c./min and controlling a temperature in the vacuum chamber in a range of 25 to 300° C.

Preferably, the filling step further comprises a step of controlling a gas pressure in the vacuum chamber ranged from 10⁻³ to 10⁻⁸ Torr, and the evaporating step further comprises a step of controlling the gas pressure of the vacuum chamber in a range of 10⁻² to 10⁻⁴ Torr.

Preferably, the high-energy electron beam is provided by one selected from a group consisting of a direct current, a RF power, an impulse direct current and a microwave current.

Preferably, the thin film has a thickness ranged from 1 nanometer to 10 micrometer.

Preferably, the substrate is one selected from a group consisting of a metal, a glass, a ceramic material, a macromolecule and a combination thereof.

Preferably, the far-infrared irradiating material comprises an alumina.

Preferably, the far-infrared irradiating material has an emission coefficient larger than 0.9 in a wavelength range of 4 to 16 micrometers.

In accordance with another aspect of the present invention, another manufacturing method for a far-infrared irradiating substrate is provided. The manufacturing method comprises steps of providing a substrate, providing a far-infrared irradiating material and evaporating the far-infrared irradiating material to form a thin film onto the substrate.

Preferably, the manufacturing method further comprises a step of treating a surface of the substrate by means of an ion source before the evaporating step, and the substrate is one selected from a group consisting of a metal, a glass, a ceramic material, a macromolecule and a combination thereof.

Preferably, the manufacturing method further comprises a step of performing an ion beam assisted deposition by means of the ion source, which contributes to the evaporating efficiency.

The above aspects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a lateral diagram of the far-infrared irradiating substrate according to a preferred embodiment of the present invention;

FIG. 2 is a schematic diagram of the manufacturing method for the far-infrared irradiating substrate according to the preferred embodiment of the present invention;

FIG. 3 is a schematic diagram that the surface of the far-infrared irradiating substrate is treated via an ion source according to a further preferred embodiment of the present invention;

FIG. 4 is a lateral diagram of another far-infrared irradiating substrate according to another preferred embodiment of the present invention;

FIG. 5 is a FIR emission distribution diagram of the far-infrared irradiating material in a wavelength range of 4 to 14 micrometers according to the present invention; and

FIG. 6 is a transmission distribution diagram of the far-infrared irradiating material in a wavelength range of 4 to 14 micrometers according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

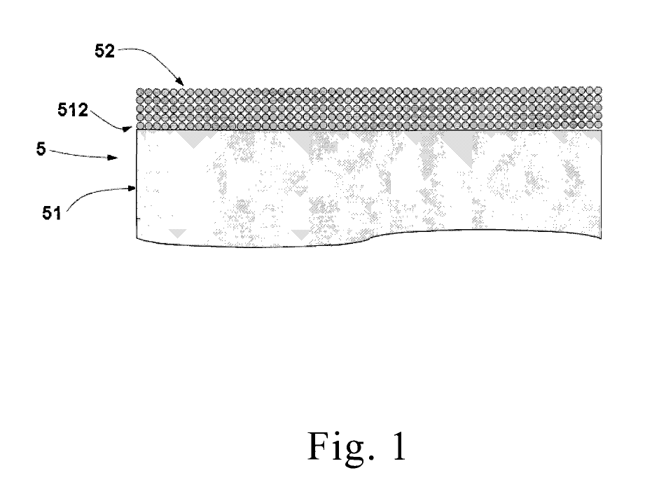

Please refer to FIG. 1, which shows a lateral diagram of the far-infrared irradiating substrate according to a preferred embodiment of the present invention. A far-infrared irradiating substrate 5 of the present invention includes a substrate 51 and a far-infrared irradiating thin film 52 with a thickness ranged from 10 nanometer to 10 micrometer, wherein the far-infrared irradiating thin film 52 is formed on a surface 512 of the substrate 51 that predetermined to be treated by an ion source. The mentioned far-infrared irradiating thin film 52 is formed by several layers of far-infrared irradiating particles piling up and the diameter of these particle is approximately several nanometers. The transmittance of the far-infrared irradiating thin film 52 in the visible wavelength is ranged from 60 to 99%, preferably is ranged from 80 to 99%. There are five layers of far-infrared irradiating particulates piling up as illustrated in FIG. 1, which is shown for a preferred embodiment of the present invention, but should not limited to the mentioned number of layers.

The suitable material for the substrate 51 can be soft substrates, such as fabrics, fibers, paper rolls, PVC sheets, macromolecular sheets, which will be described in the following embodiments, but should not limited to the abovementioned.

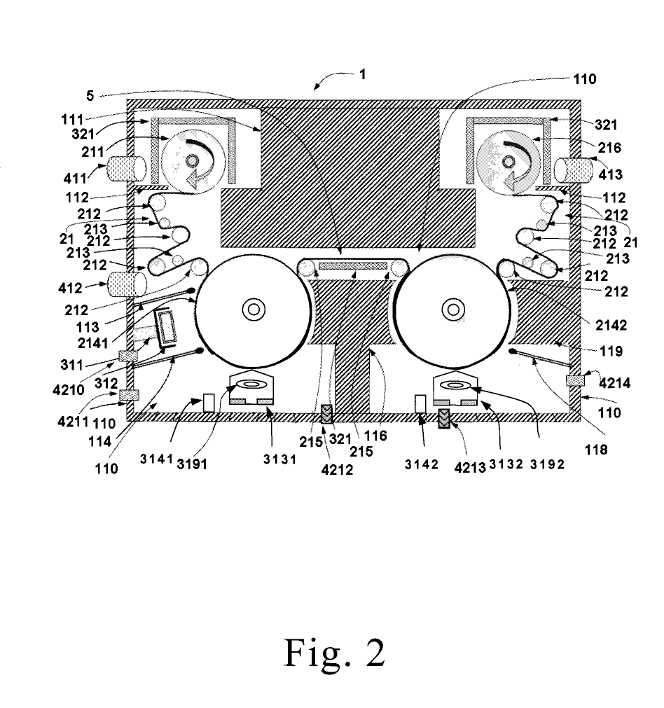

Please refer to FIG. 2, which shows a schematic diagram of the manufacturing method for the far-infrared irradiating substrate according to a preferred embodiment of the present invention. The substrate 51 in the preferred embodiment is preferably a soft substrate, which is processed though a processing equipment 1 to form the far-infrared irradiating substrate 5. The processing equipment 1 facilitates the production of the far-infrared irradiating substrate 5 in an automatic and continuous process. The processing equipment 1 includes a vacuum chamber 110, a plurality of vacuum exhausting tubes 411-413, a plurality of automatic pressure-controlling system 4210-4214 and a plurality of evaporation devices. The vacuum chamber 110 is divided into several sub-chambers by the respective partitions 112, 113, 114, 116, 118 and 119. The plurality of vacuum exhausting tubes 411-413 are disposed within the vacuum chamber 110. The plurality of evaporating devices are disposed within the vacuum chamber 110 and primarily comprises a pairs of curving modules, a pair of gears 21, a first coating wheel 2141 and a second coating wheel 2142, a first evaporation source 3131 and a second evaporation source 3132 and an ion source 311, wherein the first and the second evaporation sources 3131 and 3132 are respectively divided by the partitions 113-114, 116, and 118-119. The ion source 311 is disposed close to the first coating wheel 2141 and the first and the second evaporation sources 3131 and 3132 are respectively disposed close to the first and the second coating wheels 2141 and 2142. The curving modules include an inputting wheel 211 and an outputting wheel 216 respectively for inputting a non-processing substrate and outputting a processed substrate. The gears 21 are disposed close to the curving modules and include four pairs of conveyer wheels 212 and two pair of tension control wheels 213 that controls the tension bearing in the soft substrate. A plurality of polycolds 321 are respectively disposed close to the inputting wheel 211, close to the outputting wheel 216 and between the coating wheels 2141 and 2142, so as to absorb the steam remaining within the vacuum chamber 110 to lower down the steam pressure therein.

The method for manufacturing the far-infrared irradiating substrate 5 is performed by the mentioned processing equipment 1, so that the far-infrared irradiating product can be manufactured in an automatic and continuous process.

Fabricate the mentioned processing equipment 1, in which the main elements are described as the above. The substrate 51 to be processed is s kind of soft material, including a fabric, a fiber, a paper roller, a PVC sheet, or a macromolecular sheet. The soft substrate 51 is disposed on the inputting wheel 211 within the vacuum chamber 110 in a rolling way.

The far-infrared irradiating material of the present invention is consisted of several natural minerals, primarily including an alumina. Other natural minerals, such as a titania, a titanium diboride, a magnesia, a silica, a iron oxide, a zinc hydroxide, a zinc oxide and carbide, are also suitable.

The most surfaces of substrates, including fabrics, fibers, paper rollers, and macromolecular sheets are hydrophobic, and thus result in weak wettability, which further affects the adhesion between the far-infrared irradiating thin film 52 and the substrate 51 while depositing the far-infrared irradiating thin film 52 onto the surface 511 of the substrate 51. In order to improve the poor wettability and adhesion resulting from the mentioned hydrophobic surface, the present invention provides a surface treatment by means of an ion source to the mentioned surface, which involves a plasma treatment that makes the surface hydrophilic, so that the adhesion between the surface of the substrate and the far-infrared irradiating thin film will be highly enhanced.

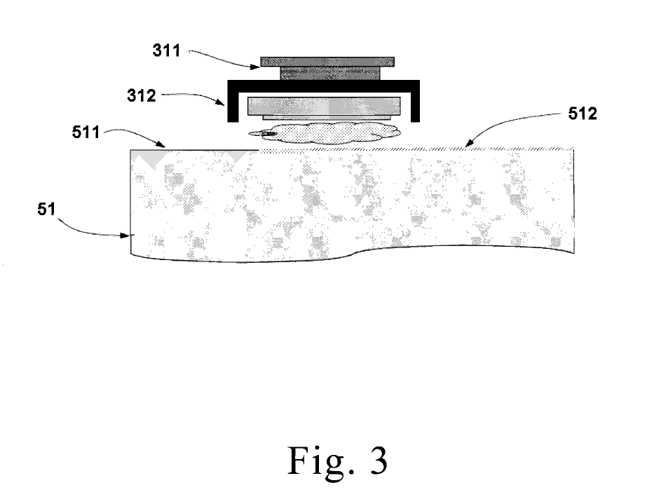

Please refer to FIG. 3, which a schematic diagram that the surface of the far-infrared irradiating substrate is treated via an ion source according to a further preferred embodiment of the present invention. The gear 21 transports the substrate 51 disposed on the inputting wheel 211 to the first coating wheel 2141 in a rolling way, followed by performing a surface treatment by means of an ion source to the substrate 51. The vacuum chamber 110 is vacuumed via the vacuum exhausting tubes 411-413, and then a mixture of oxygen and argon is fed thereinto via an inputting pipe 312 by means of a mass flow controller as well as the automatic pressure-controlling system 4210 is started simultaneously. The pressure in the vacuum chamber 110 is controlled as constant, followed by electrifying the ion source 311 with a high frequency power. Then, the mixture of oxygen and argon within the ion source 311 will be stimulated to be ionized by a high-energy electrical field, followed by feeding out the ion beam onto the surface 511 of the substrate 51 so as to form the processed surface 512. The power can be provided via a direct current, a RF power, an impulse direct current or a microwave current.

Please refer to FIGS. 1 and 2 again. After the substrate 51 is treated via the ion source, it is beneficial to the evaporation process that a mixture of oxygen and argon is fed into the vacuum chamber 110 via an inputting pipe 3141 by means of a mass flow controller (not shown) as well as the automatic pressure-controlling system 4211 or 4214 simultaneously is started to keep the constant pressure in the vacuum chamber 110. In the meantime, electrify a power source to the evaporation source 3131, wherein a filament included therein will be heated to produce thermal electrons and these thermal electrons will be driven to where the evaporation material 3191 stays through the magnetic filed. Therefore, the evaporation material 3191 is evaporated as film formation particles, and then these particles are deposited onto the surface 512 of the substrate 5 disposed on the first coating wheel 2141 passing through the evaporating region to form a far-infrared thin film 52. In the process for evaporating the far-infrared irradiating thin film 52, the polycolds 321 are disposed for capturing the steam remaining in the vacuum chamber 110 so as to save the overall vacuuming time, increase the working efficiency, acquire the preferred growing conditions for the far-infrared irradiating thin film 52, achieve a better adhesion between the processed surface 512 and the far-infrared irradiating thin film 52 and acquire the reproducibility of the far-infrared irradiating products.

Preferably, the ion source can be performed during the evaporation process to contribute to the higher depositing density of the far-infrared irradiating thin film 52 on the surface 512 of the substrate 51. Accordingly, the FIR releasing efficiency of the far-infrared irradiating product according to the present invention can be increased.

More specifically, a mixture of oxygen and argon is fed into the vacuum chamber 110 via the inputting pipe 312 by means of a mass flow controller, wherein the flow rate is controlled in a range of 10 to 200 c.c./min and simultaneously the automatic pressure-controlling system 4210 is started to maintain the pressure in the vacuum chamber 110 in a range of 1×10⁻⁴ to 1×10⁻² Torr. At this time, the oxygen and argon are generated within the ion source 311 and deposited onto the surface 512 of the substrate 51 to form the processed surface 512. The strength of the electrical voltage applying to the ion source 311 is ranged from few dozens to several hundreds of volts.

Furthermore, a mixture of oxygen and argon is fed into the vacuum chamber 110 via the inputting pipe 3141 by means of the mass flow controller and the automatic pressure-controlling system 4211 or 4212 is started simultaneously to maintain the pressure in the vacuum chamber 110 in a range of 1×10⁻⁵ to 1×10⁻¹ Torr. The mentioned steps facilitates the evaporation of the far-infrared irradiating material to generate the film formation particles, whereby these particles are directly driven to be deposited onto the substrate 51 disposed on the first coating wheel 2141 passing through the evaporation region and the far-infrared irradiating thin film 52 where the film formation particles are formed has a thickness ranged from several nanometers to several micrometers. Moreover, the evaporation rate of the evaporation material 3191 should be higher than 1 Å/s.

The thickness of the far-infrared irradiating thin film 52 can be adjusted upon the different applications in the manufacturing process according to the present invention. First, the number of layers coated on the substrate 51 can be controlled as below. The far-infrared irradiating substrate passing through the first coating wheel 2141 can be further inputted into the second coating wheel 2142 via a pair of conveyer wheels 215 for a second evaporation, so that a second layer of the film formation particles is formed on the surface 512.

In addition, the thickness of the far-infrared irradiating thin film 52 can be controlled by the curving rate and the transporting rate bearing from the curving modules and the gear 21. The curving rate is defined as the moving rate that the substrate 51 passes through the evaporation region between the first coating wheel 2141 and the second coating wheel 2142.

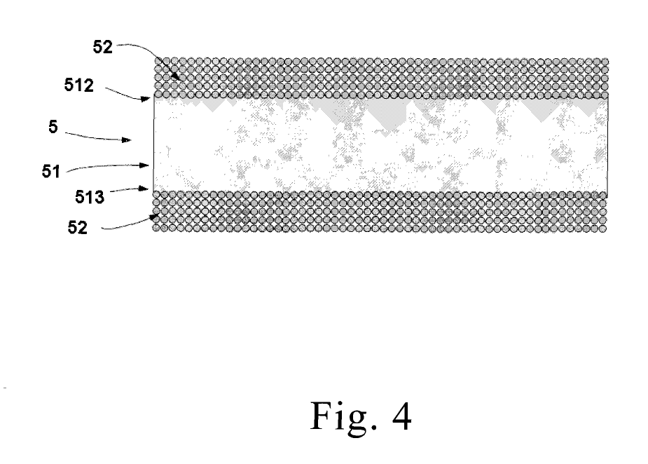

Please refer to FIG. 4, which shows a lateral diagram of another far-infrared irradiating substrate 5 according to another preferred embodiment of the present invention. In this embodiment, the respective surfaces 512 and 513 of the substrate 51 can be evaporated by reversing the substrate 51 that the surface 512 has been processed to feed into the curving modules in the manufacturing process of the present invention. Therefore, both side of the substrate 51 can be coated on the far-infrared irradiating thin films 52.

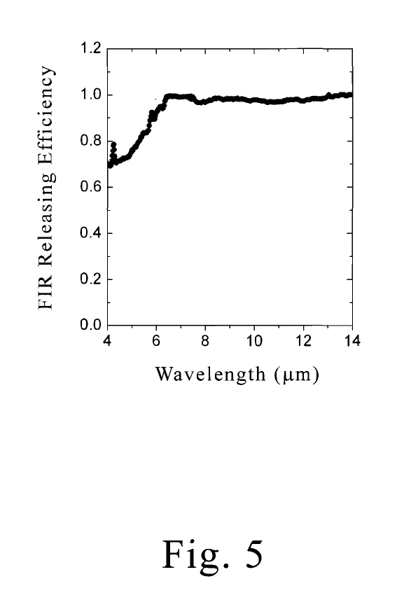

Please refer to FIG. 5, which shows a testing result of the FIR releasing efficiency of the far-infrared irradiating material according to the present invention. A black body is used as a control in the FIR releasing efficiency test. It is known that the emission coefficient in a wavelength range of 6 to 14 micrometers is higher than 0.92. Furthermore, in accordance with the US AATCC100 standard, the anti-bacterial effects of the FIR released from the far-infrared irradiating substrate of the present invention on Staphylococcus aureus. and Escherichia coli. are both up to 99.9%.

Additionally, the far-infrared irradiating material of the present invention is selected from natural minerals. The selected natural minerals are detected without an ionizing radiation and capable of releasing negative ions. Recently, the ionizing radiation is commonly deemed as a potential treat to human mutagenesis. The current commercial far-infrared irradiating product includes excess rare elements that might cause a dangerous ionizing radiation environment nearby the user. The far-infrared irradiating product provided by present invention not only has a high emission coefficient of FIR, but also do not cause a potential exposure of the ionizing radiation.

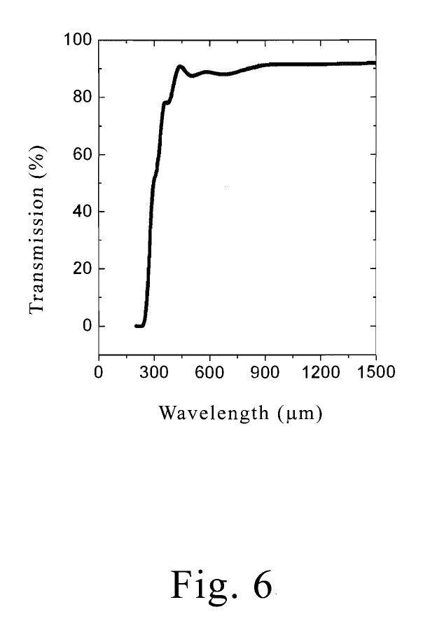

Please refer to FIG. 6, which shows a transmission distribution diagram of the far-infrared irradiating thin film according to the present invention. It is known that the transmission of the far-infrared irradiating thin film 52 is averagely up to 90% in a wavelength range of 400 to 1000 nanometers.

Furthermore, a microscopic image of the far-infrared irradiating thin film 52 coated on the polyester textile (data not shown) indicates that the far-infrared irradiating thin film 52 does not affect the appearance of the polyester textile. Another microscopic cross-section image of the far-infrared irradiating thin film 52 coated on the polyester textile (data not shown) also indicates that the far-infrared irradiating thin film 52 can be uniformly coated on the polyester textile 51.

In view of the above, the present invention provides a novel method for manufacturing a far-infrared irradiating textile by means of an evaporation deposition, wherein the far-infrared irradiating ceramic thin film can be uniformly and continuously coated on the surface of the textile. Therefore, the limitation that the content of the far-infrared ceramic powders and the larger diameter of the ceramic powder in the traditional spin process result in low adhesion might be improved. The present invention solves the mentioned defect in the current method for manufacturing the far-infrared irradiating textile.

The mentioned preferred embodiment is one way illustrated for the evaporation and deposition in which the suitable substrate is a soft and continuous substrate, but it should not be limited as the protecting scope thereby. The surface of the rigid substrate, such as a metal, a glass and a ceramic material, also can be coated with the far-infrared irradiating thin film according to the present invention.

Another advantage of the far-infrared irradiating product according to the manufacturing method of the present invention resides in that it can be performed under a room temperature, so that the textile or the macromolecular substrate coating the far-infrared irradiating thin film thereon in the conventional manufacturing process will not deform due to a overheat.

The far-infrared irradiating substrate provided by the present invention can be applied to a wide range of living appliances, including packages, natural fiber textiles, medical appliances, plastics, paper and its appliances.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method for a far-infrared irradiating substrate, comprising steps of:
providing a substrate into a vacuum chamber;
filling a first gas into the vacuum chamber;
inputting a far-infrared irradiating material into the vacuum chamber; and
evaporating and depositing the far-infrared irradiating material onto the substrate to form a thin film thereon.

2. A manufacturing method as claimed in claim 1, wherein the evaporating step further comprises a step of providing a high-energy electron beam to the vacuum chamber.

3. A manufacturing method as claimed in claim 2, wherein the evaporating step further comprises a step of treating a surface of the substrate by means of an ion source before the step of providing the high-energy electron beam to the vacuum chamber.

4. A manufacturing method as claimed in claim 3, wherein the step of treating the surface further comprises a step of filling a second gas into the vacuum chamber for igniting the ion source, the first gas includes an oxygen, and the second gas is one selected from a group consisting of an argon, an oxygen, a nitrogen and a combination thereof.

5. A manufacturing method as claimed in claim 1, wherein the evaporating step further comprises steps of controlling a gas flow rate in the vacuum chamber in a range of 10 to 200 c.c./min and controlling a temperature in the vacuum chamber in a range of 25 to 300° C.

6. A manufacturing method as claimed in claim 1, wherein the filling step further comprises a step of controlling a gas pressure in the vacuum chamber ranged from 10⁻³ to 10⁻⁸ Torr, and the evaporating step further comprises a step of controlling the gas pressure of the vacuum chamber in a range of 10⁻² to 10⁻³ Torr.

7. A manufacturing method as claimed in claim 2, wherein the high-energy electron beam is provided by one selected from a group consisting of a direct current, a RF power, an impulse direct current and a microwave current.

8. A manufacturing method as claimed in claim 2, wherein the thin film has a thickness ranged from 1 nanometer to 10 micrometer.

9. A manufacturing method as claimed in claim 2, wherein the thin layer film a transmittance ranged from 60 to 99% in a visible wavelength.

10. A manufacturing method as claimed in claim 9, wherein the transmittance is preferably ranged from 80 to 99%.

11. A manufacturing method as claimed in claim 1, wherein the substrate is one selected from a group consisting of a metal, a glass, a ceramic material, a macromolecule and a combination thereof.

12. A manufacturing method as claimed in claim 1, wherein the far-infrared irradiating material comprises an alumina.

13. A manufacturing method as claimed in claim 1, wherein the far-infrared irradiating material has a emission coefficient larger than 0.9 in a wavelength range of 4 to 16 micrometers.

14. A manufacturing method for a far-infrared irradiating substrate, comprising steps of:
providing a substrate;
providing a far-infrared irradiating material; and
evaporating the far-infrared irradiating material to form a thin film onto the substrate.

15. A manufacturing method as claimed in claim 14, further comprising a step of treating a surface of the substrate by means of an ion source before the evaporating step, and the substrate is one selected from a group consisting of a metal, a glass, a ceramic material, a macromolecule and a combination thereof.

16. A manufacturing method as claimed in claim 14, wherein the thin film has a thickness ranged from 1 nanometer to 10 micrometer, and the thin film has a transmittance ranged from 60 to 99% in a visible wavelength.

17. A manufacturing method as claimed in claim 16, wherein the transmittance is preferably ranged from 80 to 99%.

18. A manufacturing method as claimed in claim 14, further comprising steps of providing the substrate into a vacuum chamber, inputting a first gases into the vacuum chamber and controlling the gas flow rate in the vacuum chamber in a range of 10 to 200 c.c./min.

19. A manufacturing method as claimed in claim 14, wherein the far-infrared irradiating material comprises an alumina, and the far-infrared irradiating material has a emission coefficient larger than 0.9 in a wavelength of 4 to 16 micrometers.

20. A manufacturing method as claimed in claim 15, further comprising a step of performing an ion beam assisted deposition by means of the ion source.
